(19) United States
(12) Patent Application Publication
(10) Pub. No.: US 2023/0207353 A1
(43) Pub. Date: Jun. 29, 2023

(54) Transfer Device and Transfer Method

(71) Applicant: CHONGQING KONKA PHOTOELECTRIC TECHNOLOGY RESEARCH INSTITUTE CO., LTD., Chongqing (CN)

(72) Inventors: Biao TANG, Chongqing (CN); Feng ZHAI, Chongqing (CN); CHUN-LUNG HSIAO, Chongqing (CN); Zhongshan FENG, Chongqing (CN)

(21) Appl. No.: 17/614,524

(22) PCT Filed: Aug. 31, 2020
(86) PCT No.: PCT/CN2020/112699

§ 371 Date: Nov. 28, 2021

(51) Int. Cl. H01L 21/67; H01L 33/00

(52) U.S. Cl. CPC H01L 21/67144; H01L 33/005

(57) ABSTRACT

The present disclosure relates to a transfer device and a transfer method. The transfer device comprises at least one transfer unit, the transfer unit comprises: an exporting device comprising a gas flow inlet, a micro-component inlet and a micro-component exporting port, wherein the gas flow inlet, the micro-component inlet and the micro-component, exporting port are in communication with each other; a micro-component source device for storing a solution and one or more micro-components, wherein the micro-component source device comprises a micro-component outlet, and the micro-component outlet is in communication with the micro-component inlet; and a gas flow output device comprising a gas flow outlet, wherein the gas flow inlet is in communication with the gas flow outlet, and the gas flow output device is used for outputting a gas flow to the exporting device.

### CROSS REFERENCE

This application is a National Stage Filing of the PCT International Application No. PCT/CN2020/112699 filed on Aug. 31, 2020, the entirety of which is herein incorporated by reference.

### TECHNICAL FIELD

The present disclosure relates to the field of transfer of micro-components, and in particular, to a transfer device and a transfer method.

### BACKGROUND

At present, after a micro-component such as a light-emitting chip is manufactured, the micro-component such as the light-emitting chip often needs to be transferred to a structure such as a drive circuit board. However, in the related art, a plurality of temporary substrates are generally required to transfer the micro-component such as the light-emitting chip, therefore, the transfer process is relatively complex, and the efficiency is relatively low.

Therefore, how to simplify the transfer process of a micro-component such as a light emitting chip is the problem to be solved urgently.

### SUMMARY

The embodiments of the present disclosure provide a transfer device and a transfer method, which can solve the problem of complicated transfer process of a micro-component.

Some embodiments of the present disclosure provide a transfer device comprising at least one transfer unit. The transfer unit comprises: an exporting device comprising a gas flow inlet, a micro-component inlet and a micro-component exporting port, wherein the gas flow inlet, the micro-component inlet and the micro-component exporting port are in communication with each other; a micro-component source device for storing a solution and one or more micro-components, wherein the micro-component source device comprises a micro-component outlet, and the micro-component outlet is in communication with the micro-component inlet; and a gas flow output device comprising a gas flow outlet, wherein the gas flow inlet is in communication with the gas flow outlet, and the gas flow output device is used for outputting a gas flow to the exporting device.

In the transfer device above, gas is outputted to the gas inlet of the exporting device by the gas flow output device, and the gas flows out from the gas flow outlet. As the gas flow inlet, the micro-component inlet and the micro-component outlet are in communication with each other, in the process of the gas flow inflowing from the gas inflow inlet and outflowing from the micro-component outlet, at the micro-component inlet, the pressure close to the exporting device side is lower than the pressure close to the micro-component source device side, thereby creating a suction force to draw the liquid drop wrapping the micro-component in the micro-component source device into the exporting device and out from the micro-component exporting port. The transfer of a micro-component to a specified position can be achieved as long as the micro-component outlet is aligned to the specified position. The transfer device may comprise a plurality of transfer units, such that a plurality of micro-components can be transferred at one time, and thus the present scheme can be used for mass transfer of micro-components.

In some exemplary implementations, the transfer unit further comprises a valve located on a connection pipeline between the micro-component outlet and the micro-component inlet. The valve is opened in a case where a differential pressure between a first pressure and a second pressure is greater than a predetermined differential pressure, wherein the predetermined differential pressure is greater than 0, the first pressure is a pressure on the side of the valve close to the micro-component source device, and the second pressure is a pressure on the side of the valve close to the exporting device. By controlling the first pressure at the micro-component outlet to be greater than the second pressure at the micro-component inlet, a differential pressure is formed between the micro-component outlet and the micro-component inlet, and the micro-component moves from the micro-component outlet into the exporting device through the micro-component inlet under the effect of the differential pressure.

In some exemplary implementations, the micro-component inlet is located between the gas flow inlet and the micro-component exporting port. When being output from the gas flow outlet, the gas flow passes through not only the gas flow inlet, but also the micro-component inlet, such that the pressure on the side of the valve close to the micro-component inlet changes, by adjusting the flow quantity of the gas flow, the differential pressure between the two sides of the valve can reach a predetermined differential pressure, so that liquid drops carrying the micro-components pass from the micro-component source device, through the micro-component outlet and the micro-component inlet, and into the exporting device. In this solution, by controlling the output gas flow, the liquid drops can be driven to move so as to be exported from the exporting device, or the liquid drops can be driven to move from the micro-component source device into the exporting device.

In some exemplary implementations, the gas flow output device comprises: a first pipeline, wherein one end of the first pipeline is the gas flow outlet; and a gas flow control unit connected to the other end of the first pipeline, wherein the gas flow control unit is used for controlling a flow quantity of the gas flow entering the first pipeline. The structure is relatively simple, the transfer process of the micro-component is further precisely controlled, and the structure of the transfer device and the transfer process of the micro-components are further simplified.

In some exemplary implementations, the exporting device comprises: a second pipeline comprising the micro-component inlet, the gas flow inlet and the micro-component exporting port. The structure is simple, and the structure of the transfer device and the micro-component transfer process are further simplified.

In some exemplary implementations, the second pipeline comprises a first pipeline body and a first material layer, the first material layer is provided on an inner wall of the first pipeline body, and a hydropathicity/hydrophobicity of a material of the first material layer is opposite to a hydropathicity/hydrophobicity of the solution, so that the solution does not wet the inner wall of the pipeline of the first body, but is correspondingly repelling, thereby facilitating the liquid drops wrapping the micro-components in flowing out of the exporting device from the second pipeline, so as to realize the transfer of the micro-components.

In some exemplary implementations, the micro-component source device comprises: a third pipeline, wherein an outlet of the third pipeline is the micro-component outlet; and a storage unit having an outlet in communication with an inlet of the third pipeline, wherein the storage unit is used for storing the solution and the micro-components. The structure is simple, and the structure of the transfer device and the micro-component transfer process are further simplified.

In some exemplary implementations, an angle between a central axis of the third pipeline and a central axis of the second pipeline is greater than 0° and less than 90°, which facilitates movement of the micro-components from the third pipeline into the second pipeline, thereby improving the transfer efficiency of the micro-components.

In some exemplary implementations, the third pipeline comprises a second pipeline body and a second material layer, the second material layer is provided on an inner wall of the second pipeline body, and a hydropathicity/hydrophobicity of a material of the second material layer is opposite to a hydropathicity/hydrophobicity of the solution, so that the solution does not wet the inner wall of the pipeline of the second body, but is correspondingly repelling, thereby facilitating the liquid drops wrapping the micro-components in flowing out of the exporting device from the second pipeline, so as to realize the transfer of the micro-components.

In some exemplary implementations, there are a plurality of transfer units, and the plurality of transfer units are arranged at intervals in a predetermined direction, or the plurality of transfer units form a transfer unit matrix having multiple rows and multiple columns.

Based on the same inventive concept, some embodiments of the present disclosure provide a transfer method, comprising: providing a predetermined structure; storing a solution and one or more micro-components into a micro-component source device in any one of the transfer devices; controlling the gas flow output device in the transfer device to output a gas flow at a predetermined flow quantity, such that a liquid drop of the solution carrying a micro-component is exported to a predetermined position of the predetermined structure; and removing the solution.

According to the transfer method above, by controlling the gas flow output device to output a gas flow at a predetermined flow quantity, the liquid drop carrying the micro-component moves out of the transfer device, and then moves to a predetermined position of a predetermined structure (for example, on a drive circuit board), and then the solution in the liquid drops are removed, so that the micro-component is electrically connected to the predetermined structure. By virtue of the scheme, the transfer of a micro-component is realized, the process of transferring a micro-component is simplified, and the efficiency of transferring a micro-component is improved.

In some exemplary implementations, the transfer device further comprises a valve located on a connection pipeline between the micro-component outlet of the micro-component source device and the micro-component inlet of the exporting device, a predetermined flow quantity of gas flow causes the valve to open, such that a predetermined number of liquid drops enter the exporting device from the micro-component source device. By controlling the flow quantity of the gas flow, a predetermined differential pressure is formed between the micro-component outlet of the micro-component source device and the micro-component inlet of the exporting device, and the predetermined differential pressure causes a predetermined number of liquid drops to enter the exporting device from the micro-component source device.

In some exemplary implementations, removing the solution comprises heating the predetermined structure to evaporate the solution.

In some exemplary implementations, a mass density of each of the one or more micro-component is greater than or equal to a mass density of the solution, so that the micro-component placed at the predetermined position achieves accurate alignment.

In some exemplary implementations, each of the one or more micro-components comprises a first part and a second part, the first part comprises an electrode, a mass density of the first part is greater than a mass density of the second part, and the mass density of the first part is greater than the mass density of the solution, so that the micro-component can be placed at the predetermined position more accurately, thereby better realizing accurate alignment.

In some exemplary implementations, each of the one or more micro-components comprises a body structure part, a first electrode and a second electrode, wherein the body structure part is in a spherical shape, and the first electrode and the second electrode are located on a surface of the body structure part at intervals.

In some exemplary implementations, the second electrode is located at the periphery of the first electrode, and the second electrode is an annular electrode; or the second electrode comprises a plurality of electrode parts spaced apart from each other, and lines connecting centers of the plurality of electrode parts form a closed figure. Such an electrode structure can further ensure accurate alignment of the micro-component and the predetermined position.

In some exemplary implementations, the predetermined position has a groove adapted to the micro-component, a metal channel and a metal hole are provided on the wall of the groove, and after the solution is removed, the metal hole is in contact with the first electrode and the metal channel is in contact with the second electrode. The metal channel is provided as a continuous annular metal channel, and the second electrode is provided in a shape which is able to comprise a plurality of spaced electrode parts, which is beneficial to flow of unnecessary solder flux into the vacant part of the annular metal channel (that is, the part of the annular metal channel that is not in contact with the second electrode) when the micro-component is bonded, in this way, overflowing of solder flux to short-circuit the micro-component can be effectively avoided.

### BRIEF DESCRIPTION OF THE DRAWINGS

FIG. 1 is a structural schematic diagram of a transfer device according to the embodiments of the present disclosure;

FIG. 2 is a schematic diagram of a device comprising a transfer device and a predetermined structure according to the embodiments of the present disclosure;

FIG. 3 is a flowchart of a transfer method according to the embodiments of the present disclosure;

FIG. 4 is a schematic diagram illustrating a partial structure of FIG. 2 according to the embodiments of the present disclosure;

FIG. 5 is a schematic diagram of a micro-component and a groove according to the embodiments of the present disclosure;

FIG. 6 is a schematic diagram of a device comprising a plurality of transfer units and a predetermined structure according to the embodiments of the present disclosure;

FIG. 7 is a schematic diagram of yet another device comprising a plurality of transfer units and a predetermined structure according to the embodiments of the present disclosure;

FIG. 8 is a schematic diagram of still another device comprising a plurality of transfer units and a predetermined structure according to the embodiments of the present disclosure.

### DESCRIPTION OF REFERENCE NUMERALS

10, exporting device; 11, second pipeline; 20, micro-component source device; 21, micro-component; 210, body structure part; 211, first electrode; 212, second electrode; 22, liquid drop; 23, third pipeline; 24, storage unit; 30, gas flow output device; 31, first pipeline; 32, gas flow control unit; 40, predetermined structure; 41, groove; 410, metal channel; and 411, metal hole.

### DETAILED DESCRIPTION OF THE EMBODIMENTS

In order to facilitate understanding of the present disclosure, the present disclosure will be described will be described below more comprehensively hereinafter with reference to the accompanying drawings. Preferred embodiments of the present disclosure are shown in the drawings. The present disclosure may, however, be embodied in many different forms and is not limited to the embodiments set forth herein. Rather, these embodiments are provided so that the present disclosure will be fully and thoroughly understood.

Unless defined otherwise, all technical and scientific terms used herein have the same meaning as commonly understood by a person having ordinary skill in the art to which the present disclosure belongs. The terms used herein in the description of the present disclosure are for the purpose of describing embodiments only and are not intended to be limiting of the present disclosure.

As introduced in the background art, the transfer process of a micro-component such as a light-emitting chip in the related art is relatively complex. The embodiments of the present disclosure provide a transfer device and a transfer method, which can address the problem of complicated transfer process of a micro-component.

Some embodiments of the present disclosure provide a transfer device. As shown in FIG. 1, the transfer device comprises at least one transfer unit. The transfer unit comprises an exporting device 10, a micro-component source device 20 and a gas flow output device 30. The exporting device 10 comprises a gas flow inlet, a micro-component inlet and a micro-component exporting port. The gas flow inlet, the micro-component inlet and the micro-component exporting port are in communication each other. The micro-component source device 20 is used for storing a solution and one or more micro-components, wherein the micro-component source device 20 comprises a micro-component outlet, and the micro-component outlet is in communication with the micro-component inlet. The gas flow output device 30 comprises a gas flow outlet, and the gas flow inlet is in communication with the gas flow outlet. The gas flow output device 30 is configured to output a gas flow to the exporting device 10. The micro-component enters the exporting device 10 from the micro-component source device 20 under the action of the gas flow and is exported from the micro-component exporting port.

In the transfer device above, gas is outputted to the gas inlet of the exporting device by the gas flow output device, and the gas flows out from the gas flow outlet. As the gas flow inlet, the micro-component inlet and the micro-component outlet are in communication with each other, in the process of the gas flow inflowing from the gas inflow inlet and outflowing from the micro-component outlet, at the micro-component inlet, the pressure close to the exporting device side is lower than the pressure close to the micro-component source device side, thereby creating a suction force to draw the liquid drop wrapping the micro-component in the micro-component source device into the exporting device and out from the micro-component exporting port. The transfer of a micro-component to a specified position can be achieved as long as the micro-component outlet is aligned to the specified position. The transfer device may comprise a plurality of transfer units, such that a plurality of micro-components can be transferred at one time, and thus the present scheme can be used for mass transfer of micro-components.

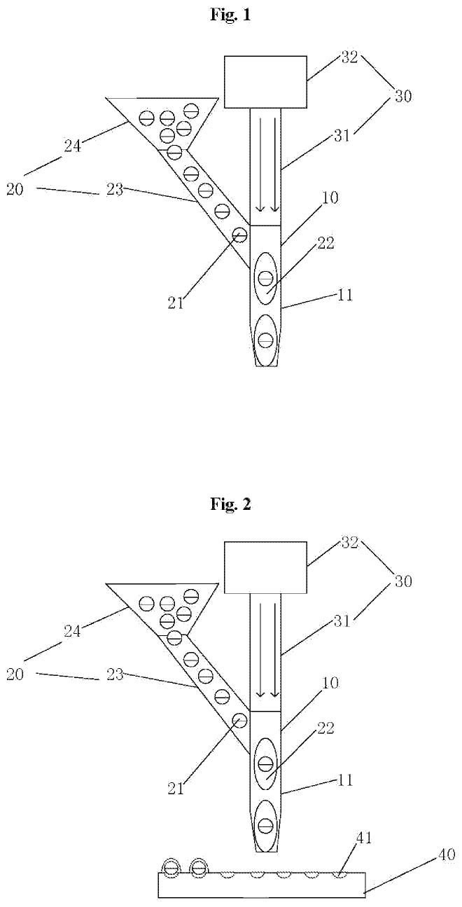

As an exemplary implementation, as shown in FIGS. 1 and 2, the solution may wrap the micro-component to form a liquid drop 22, and the liquid drop 22 wrapping the micro-component moves out of the exporting device 10 under the action of the gas flow output by the gas flow output device 30.

To further precisely control the transfer process of the micro-components, as shown in FIGS. 1 and 2, the transfer unit further comprises a valve located on a connection pipeline between the micro-component outlet and the micro-component inlet, when a differential pressure between a first pressure and a second pressure is greater than a predetermined differential pressure, the valve is opened under the action of a differential pressure of an inner pressure and an outer pressure, wherein the predetermined differential pressure is greater than 0, the first pressure is a pressure on the side of the valve close to the micro-component source device 20, the second pressure is a pressure on the side of the valve close to the exporting device 10, the side of the valve close to the micro-component source device 20 is the micro-component outlet, and the side of the valve close to the export device 10 is the micro-component inlet. By controlling the first pressure at the micro-component outlet to be greater than the second pressure at the micro-component inlet, a differential pressure is formed between the micro-component outlet and the micro-component inlet, such that the micro-component is wrapped by the liquid to move from the micro-component outlet into the exporting device through the micro-component inlet under the effect of the differential pressure.

As an exemplary implementation, a person having ordinary skill in the art would be able to set a suitable predetermined differential pressure according to practical situations.

In some exemplary embodiments of the present disclosure, as shown in FIGS. 1 and 2, the micro-component inlet is located between the gas flow inlet and the micro-component exporting port. When being output from the gas flow outlet, the gas flow passes through not only the gas flow inlet, but also the micro-component inlet, such that the pressure on the side of the valve close to the micro-component inlet changes, by adjusting the flow quantity of the gas flow, the differential pressure between the two sides of the valve can reach a predetermined differential pressure, so that liquid drops carrying the micro-components pass from the micro-component source device, through the micro-component outlet and the micro-component inlet, and into the exporting device. In this solution, by controlling the output gas flow, the liquid drops can be driven to move so as to be exported from the exporting device, or the liquid drops can be driven to move from the micro-component source device into the exporting device.

Of course, the positional of the micro-component inlet is not limited to the specific location described above. For example, the micro-component inlet may all be located on the top side of the exporting device 10. Of course, if the micro-component inlet is not in the specific position above, it may not be possible to control the state of the valve through the gas flow, and in this case, a corresponding control device may be needed to control the state of the valve. A person having ordinary skill in the art would be able to rationally set the relative positions of the micro-component inlet, the gas flow inlet and the micro-component outlet according to actual situations, as long as the setting can satisfy that gas flow inflowing from the gas flow inlet can move micro-components in the exporting device out of the exporting device.

In practical application, in some exemplary embodiments of the present disclosure, as shown in FIGS. 1 and 2, the gas flow output device 30 comprises a first pipeline 31, one end of the first pipeline 31 is the gas flow outlet, that is, the gas flow outputted from the gas flow output device 30 flows in the first pipeline 31, and is output from the gas flow outlet. As the gas flow inlet is in communication with the gas flow outlet, the gas flow output by the gas flow output device 30 is output to the gas flow inlet of the exporting device 10 and then is input to the exporting device 10, and furthermore, the gas flow input to the exporting device 10 outputs the micro-components to the exporting device 10 to realize the transfer of the micro-components. The structure is simple, and the structure of the transfer device and the micro-component transfer process are further simplified.

In order to further precisely control the transfer process of the micro-components, and simplify the transfer process of the micro-components, as shown in FIGS. 1 and 2, the gas flow output device 30 further comprises a gas flow control unit 32. The air flow control unit 32 is connected to the other end of the first pipeline 31 and is used for controlling a flow quantity of the gas flow entering the first pipeline 31. In some exemplary implementations, the gas flow control unit may be a flow control valve, and a flow quantity of the gas flow entering the first pipeline 31 is controlled by the flow control valve.

In order to further facilitate the control of the state of the flow control valve, so as to further precisely control the flow quantity of the outputted gas flow, and simplify the transfer process of the micro-components, the gas flow control unit of the exemplary embodiment of the present disclosure may also comprise a controller, the controller sends a control signal to the flow control valve, and the flow control valve adjusts the degree of opening according to the control signal, so as to control the flow quantity of the gas flow in the first pipeline 31.

In practical application, the control unit may be a gas flow controller for controlling the flow quantity and flow rate of the injected gas flow.

In practical application, the gas flow control unit may further comprise a pressure sensor. The pressure of the gas flow in the first pipeline is obtained by detecting a signal of the pressure sensor, the pressure of the gas flow in the first pipeline is controlled by controlling the degree of opening of the flow control valve, and the transfer to the micro-components is realized by controlling the flow quantity of the gas flow and the pressure of the gas flow.

In some embodiments, as shown in FIGS. 1 and 2, the exporting device 10 comprises a second pipeline 11. The second pipeline 11 comprises the micro-component inlet, the gas flow inlet and the micro-component exporting port. The gas flow output device 30 inputs gas flow into the second pipeline 11 from the gas flow inlet, and the micro-components moving in from the micro-component inlet also move in the second pipeline 11, and move out of the micro-component exporting port from the micro-component inlet, so as to move the micro-component out of the exporting device 10 under the action of the gas flow output by the gas flow output device 30. The structure is simple, and the structure of the transfer device and the micro-component transfer process are further simplified.

In some embodiments, the second pipeline comprises a first pipeline body and a first material layer. The first material layer is provided on an inner wall of the first pipeline body, and a hydropathicity/hydrophobicity of a material of the first material layer is opposite to a hydropathicity/hydrophobicity of the solution. As a hydropathicity/hydrophobicity of a material of the first material layer is opposite to a hydropathicity/hydrophobicity of the solution, the solution does not wet the inner wall of the pipeline of the first body, but is correspondingly repelling, thereby facilitating the liquid drops wrapping the micro-components in flowing out of the exporting device from the second pipeline, so as to realize the transfer of the micro-components.

In some other embodiments of the present disclosure, as shown in FIGS. 1 and 2, the micro-component source device 20 comprises a third pipeline 23. The outlet of the third pipeline 23 is the micro-component outlet, and the micro-components in the third pipeline 23 moves out from the micro-component outlet. When the micro-component outlet is in communication with the micro-component inlet, the micro-components moving to the micro-component outlet are then moved to the micro-component inlet, so that the micro-components in the third pipeline 23 move into the exporting device 10, so as to facilitate the transfer of the micro-components. The structure is simple, and the structure of the transfer device and the micro-component transfer process are further simplified.

In order to further simplify the transfer process, in some exemplary embodiments of the present disclosure, as shown in FIGS. 1 and 2, the micro-component source device 20 comprises a storage unit 24, and an outlet of the storage unit 24 is in communication with an inlet of the third pipeline 23. The storage unit 24 is used for storing the solution and the micro-components. The solution and the micro-components stored in the storage unit 24 are moved into the exporting device 10 through the third pipeline 23, and then the liquid drops 22 wrapping the micro-components move out of the exporting device 10, so as to realize the transfer of the micro-components 21.

Of course, in practical application, the device may also not comprise the storage unit, and in this case, during application, it may be necessary to directly inject a predetermined amount of solution and micro-components into the third pipeline.

In yet other some embodiments, as shown in FIGS. 1 and 2, an angle between a central axis of the third pipeline 23 and a central axis of the second pipeline 11 is greater than 0° and less than 90°, so that it is convenient for the micro-component to move from the third pipeline 23 to the second pipeline 11, facilitating the connection of the third pipeline 23 to the second pipeline 11, and facilitating movement of the micro-components 21 from the third pipeline 23 into the second pipeline 21, thereby improving the transfer efficiency of the micro-components.

In some embodiments, the third pipeline comprises a second pipeline body and a second material layer. The second material layer is provided on an inner wall of the second pipeline body, and a hydropathicity/hydrophobicity of a material of the second material layer is opposite to a hydropathicity/hydrophobicity of the solution, so that the solution does not wet the inner wall of the pipeline of the second body, but is correspondingly repelling, thereby facilitating the liquid drops wrapping the micro-components in flowing out of the exporting device from the second pipeline, so as to realize the transfer of the micro-components.

In order to further increase the amount of transfer of the micro-components per unit time, as shown in FIG. 6, in some exemplary embodiments of the present disclosure, there may be a plurality of transfer units, and each transfer unit comprises an exporting device 10, and the plurality of transfer units are arranged at intervals in a predetermined direction. The predetermined direction may be a horizontal direction, a vertical direction, etc. Of course, the horizontal direction and the vertical direction are relative, and with the difference of the reference plane, the horizontal direction and the vertical direction may change correspondingly. The plurality of transfer units may enable transfer of a large amount of micro-components at one time, i.e. achieving transfer of massive micro-components. Specifically, the spacing, in the predetermined direction, between the micro-component exporting ports of the exporting devices 10 of two adjacent transfer units is equal to the spacing between two adjacent predetermined positions in the predetermined direction, facilitating placement of a micro-component in a groove 41 at its corresponding predetermined position; or, the spacing, in the predetermined direction, between the micro-component exporting ports of the exporting devices 10 of two adjacent transfer units is an integer multiple of the spacing between two adjacent predetermined positions in the predetermined direction, facilitating placement of a micro-component in a groove 41 at its corresponding predetermined position.

In some other embodiments of the present disclosure, as shown in FIG. 7, there may be a plurality of transfer units, and the plurality of transfer units form a transfer unit matrix having multiple rows and multiple columns, and transfer of multiple micro-components can be achieved at one time by a transfer unit matrix. As an exemplary implementation, the spacing between the micro-component outlets of the exporting device 10 of the two adjacent transfer units on each row or each column is equal to the spacing between the two adjacent predetermined positions on each row or each column, facilitating placement of a micro-component in a groove 41 at its corresponding predetermined position; or, the spacing between the micro-component outlets of the exporting device 10 of the two adjacent transfer units on each row or each column is an integer multiple of the spacing between the two adjacent predetermined positions on each row or each column, facilitating placement of a micro-component in a groove 41 at its corresponding predetermined position. In this way, the amount of transfer of the micro-components per unit time can be further increased.

Of course, in practice applications, the arrangement of the plurality of transfer units is not limited to the foregoing matrix form. A person having ordinary skill in the art may select a proper arrangement manner according to actual situations, so as to implement transfer of a large amount of micro-components.

It needs to be noted that the transfer device in the embodiments of the present disclosure can be applied to the transfer process of various micro-components. In an exemplary application of the embodiments of the present disclosure, the transfer device is used for transferring at least one of an LED chip, an OLED chip, a Micro LED chip and a Mini LED chip.

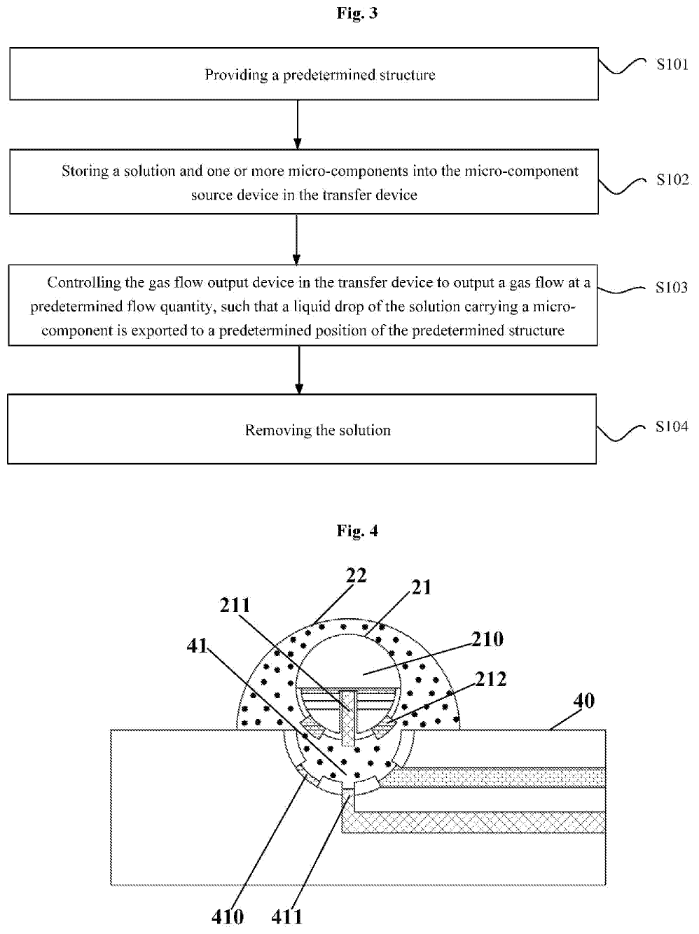

Some other embodiments of the present disclosure provide a transfer method. As shown in FIG. 3, the transfer method comprises the following operations.

In operation S101, a predetermined structure 40 as shown in FIG. 2 is provided.

In operation S102, a solution and one or more micro-components are stored into a micro-component source device 20 in any one of the transfer devices, as shown in FIG. 2.

In operation S103, a gas flow output device 30 in the transfer device is controlled to output a predetermined flow quantity of gas flow, such that a liquid drop 22 of the solution carrying a micro-component is exported to a predetermined position of the predetermined structure 40.

In operation S104, the solution is removed.

In the solution above, by controlling the gas flow output device to output a gas flow at a predetermined flow rate, the liquid drop carrying the micro-component moves out of the transfer device, and then moves to a predetermined position of a predetermined structure (for example, on a drive circuit board), and then the solution in the liquid drops are removed, so that the micro-component is electrically connected to the predetermined structure. By virtue of the scheme, the transfer of a micro-component is realized, the process of transferring a micro-component is simplified, and the efficiency of transferring a micro-component is improved.

In some exemplary embodiments of the present disclosure, as shown in FIG. 2, the transfer device further comprises a valve located on a connection pipeline between a micro-component outlet of the micro-component source device 20 and a micro-component inlet of the exporting device 10, a predetermined flow quantity of gas flow causes the valve to open, such that a predetermined number of liquid drops 22 enter the exporting device 10 from the micro-component source device 20. By controlling the flow rate of the gas flow, a predetermined differential pressure is formed between the micro-component outlet of the micro-component source device and the micro-component inlet of the exporting device, and the predetermined differential pressure causes a predetermined number of liquid drops to enter the exporting device from the micro-component source device.

The solution in the embodiments of the present disclosure has two effects: first, transporting the micro-components via a fluid; second, ensuring that the micro-components are located at corresponding soldering positions in a suspended state on a predetermined structure such as a substrate, so as to facilitate alignment.

As an exemplary implementation, a person having ordinary skill in the art would be able to set a suitable predetermined differential pressure according to practical situations.

As an exemplary implementation, the predetermined number may be one, two, three, five, etc., and a person having ordinary skill in the art would be able to control the predetermined flow quantity according to actual situations, so as to control the predetermined number of liquid drops to enter the exporting device from the micro-component source device.

In order to further improve the transfer efficiency and simplify the transfer process, in some embodiments, removing the solution comprises: heating the predetermined structure to evaporate the solution. After the solution is removed, only the micro-component is left at the predetermined position, and an electrode of the micro-component is electrically connected to an electrode of the predetermined structure, so as to ensure the normal operation of the micro-component.

Of course, in practical application, the welding may be performed after the solution is removed, and certainly, the solution may also be removed in other suitable manners.

In order to achieve accurate alignment of the micro-components placed at predetermined positions, in some exemplary embodiments of the present disclosure, a mass density of each of the one or more micro-components is greater than or equal to a mass density of the solution.

In some exemplary embodiments, each of the one or more micro-components comprises a first part and a second part, and the first part comprises an electrode. A mass density of the first part is greater than a mass density of the second part, the mass density of the first part is greater than the mass density of the solution, and the mass density of the second part is less than the mass density of the solution, enabling the first part comprising the electrode to sink in the solution and the second portion excluding the electrodes to float in the solution. Furthermore, the overall mass density of the micro-component is slightly greater than or equal to the mass density of the solution, so that when the micro-component is in the solution, the overall micro-component will tend to keep the first part comprising the electrode downwards and the second part not comprising the electrodes upwards, so as to more accurately place the micro-components at the predetermined position, thereby better achieving accurate alignment.

In some other exemplary embodiments, as shown in FIG. 4, the micro-component 21 comprises a body structure part 210, a first electrode 211 and a second electrode 212. The body structure part 210 is in a spherical shape, and the first electrode 211 and the second electrode 212 are located on a surface of the body structure part 210 at intervals. The micro-component may be a light-emitting chip.

Of course, the micro-components in the embodiments of the present disclosure are not limited to the spherical structures, and may also be structures of other shapes.

In some other embodiments of the present disclosure, as shown in FIG. 4, the second electrode 212 is located at the periphery of the first electrode 211, and the second electrode 212 is an annular electrode; or the second electrode 212 comprises a plurality of electrode parts spaced apart from each other, and lines connecting centers of the plurality of electrode parts form a closed figure. Such an electrode structure can further ensure accurate alignment of the micro-component and the predetermined position.

Of course, the annular electrode is not limited to a circular ring, and may also be a square ring, a triangular ring, etc., and a person having ordinary skill in the art would be able to set an appropriate ring shape for the electrode according to practical situations.

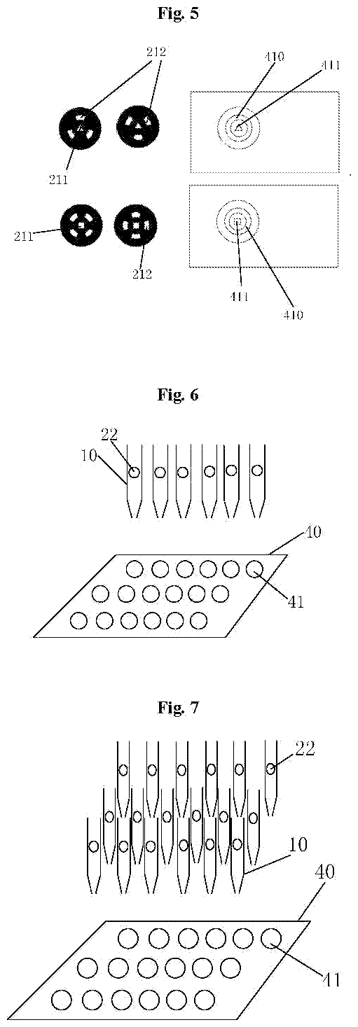

In some exemplary embodiments of the present disclosure, as shown in FIGS. 4 and 5, the predetermined position has a groove 41 adapted to the micro-component, and a metal channel 410 and a metal hole 411 are provided on the wall of the groove 41. After the solution is removed, the metal hole 411 is in contact with the first electrode 211, and the metal channel 410 is in contact with the second electrode 212. As an exemplary implementation, the metal channel 410 is provided as a continuous annular metal channel 410, and the second electrode 212 is provided in a shape which is able to comprise a plurality of spaced electrode parts, which is beneficial to flow of unnecessary solder flux into the vacant part of the annular metal channel 410 (that is, the part of the annular metal channel 410 that is not in contact with the second electrode 212) when the micro-component is bonded, in this way, overflowing of solder flux to short-circuit the micro-component can be effectively avoided.

To achieve the transfer of multiple micro-components at one time, as shown in FIG. 6, the transfer device comprises a plurality of transfer units, and the plurality of the transfer units are arranged at intervals in a predetermined direction. There are a plurality of predetermined positions, and the plurality of predetermined positions form a plurality of predetermined position rows successively arranged at intervals in the predetermined direction. The gas flow output device in the transfer device is controlled to output a predetermined flow quantity of gas flow, so that liquid drops 22 of the solution carrying the micro-components are exported to predetermined positions of the predetermined structure 40. This process comprises: simultaneously using a plurality of transfer units to respectively export a plurality of liquid drops 22 to the predetermined positions of the plurality of predetermined position rows, so that the liquid drops 22 are provided at the predetermined positions of each of the predetermined position rows, wherein one of the transfer units is used for sequentially placing a plurality of liquid drops 22 at a plurality of predetermined positions in one of the predetermined position rows. As an exemplary implementation, the spacing, in the predetermined direction, between the micro-component exporting ports of the exporting devices 10 of two adjacent transfer units is equal to the spacing between two adjacent predetermined positions in the predetermined direction, facilitating placement of a micro-component in a groove 41 at the predetermined position; or, the spacing, in the predetermined direction, between the micro-component exporting ports of the exporting devices 10 of two adjacent transfer units is an integer multiple of the spacing between two adjacent predetermined positions in the predetermined direction, facilitating placement of a micro-component in a groove 41 at the predetermined position.

In order to achieve the transfer of more micro-components at one time, in some other embodiments of the present disclosure, as shown in FIG. 7, there are a plurality of transfer units, each transfer unit comprises an exporting device 10, and the plurality of the transfer units form a transfer unit matrix having multiple rows and multiple columns. The predetermined structure 40 has a plurality of the predetermined positions, and the plurality of the predetermined positions form a predetermined position matrix. The gas flow output device in the transfer device is controlled to output a predetermined flow quantity of gas flow, so that liquid drops 22 of the solution carrying the micro-components are exported to predetermined positions of the predetermined structure 40. This process comprises: simultaneously using the plurality of transfer units to respectively export a plurality of liquid drops 22 to a plurality of predetermined positions, and one of the transfer units is used for providing one of the liquid drops 22 in a groove 41 at one of the predetermined positions. As an exemplary implementation, the spacing between the micro-component outlets of the exporting device 10 of the two adjacent transfer units on each row or each column is equal to the spacing between the two adjacent predetermined positions on each row or each column, facilitating placement of a micro-component in a groove 41 at the predetermined position; or, the spacing between the micro-component outlets of the exporting device 10 of the two adjacent transfer units on each row or each column is an integer multiple of the spacing between the two adjacent predetermined positions on each row or each column, facilitating placement of a micro-component in a groove 41 at the predetermined position.

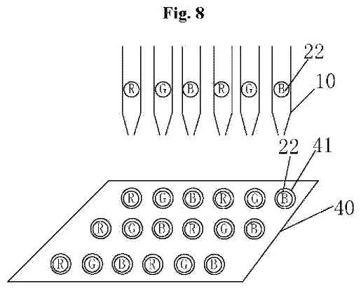

In specific applications, as shown in FIG. 8, each transfer unit comprises one exporting device 10. In order to realize transfer of chips with different light-emitting colors, the chips in the chip source devices of different transfer units may be set to chips with different light-emitting colors, and may be a red light-emitting chip, a green light-emitting chip and a blue light-emitting chip. In FIG. 8, R represents the liquid drop 22 that wraps the chip emitting red light, G represents the droplet 22 that wraps the chip emitting green light, and B represents the liquid drop 22 that wraps the chip emitting blue light. The liquid drops 22 wrapping chips emitting light of multiple colors are exported to the groove 41, so that the chips emitting light of multiple colors can be directly transferred at one time, improving the transfer efficiency of the chips and facilitating colorization.

In some exemplary embodiments of the present disclosure, each of the one or more micro-components comprises at least one of an LED chip, an OLED chip, a Micro LED chip and a Mini LED chip; and the predetermined structure 40 is a drive circuit board, so as to achieve the transfer of a plurality of chips to the drive circuit board.

Of course, in practical applications, the corresponding transferred micro-component in the transfer method of the embodiments of the present disclosure may be any micro-component that can be transferred by the transfer device, and a person having ordinary skill in the art would be able to choose to apply the method to a suitable micro-component transfer process according to practical situations.

In addition, the predetermined structure of the embodiments of the present disclosure is not limited to the drive circuit board, and a person having ordinary skill in the art would be able to determine a corresponding predetermined structure according to actual situations, such as the type of the micro-component and the structure to be formed correspondingly.

The solution of the embodiments of the present disclosure may be a non-corrosive solution that can be easily removed by evaporation, and may be ethanol, deionized water, etc.

It should be understood that the application of the present disclosure is not limited to the examples above, and a person having ordinary skill in the art can make improvements or modifications according to the above descriptions, and all these improvements and modifications shall belong to the scope of protection of the appended claims of the present disclosure.

1. A transfer device, comprising at least one transfer unit, wherein the transfer unit comprises:
an exporting device comprising a gas flow inlet, a micro-component inlet and a micro-component exporting port., wherein the gas flow inlet, the micro-component inlet and the micro-component outlet are in communication with each other;
a micro-component source device for storing a solution and one or more micro-components, wherein the micro-component source device comprises a micro-component outlet, and the micro-component outlet is in communication with the micro .component inlet; and
a gas flow output device comprising a gas flow outlet, wherein the gas flow inlet is in communication with the gas flow outlet, and the gas flow output device is used for outputting a gas flow to the exporting device.

2. The transfer device according to claim 1, wherein the transfer unit further comprises a valve located on a connection pipeline between the micro-component outlet and the micro-component inlet, wherein the valve is opened in a case where a differential pressure between a first pressure and a second pressure is greater than a predetermined differential pressure, wherein the predetermined differential pressure is greater than 0, the first pressure is a pressure on the side of the valve close to the micro-component source device, and the second pressure is a pressure on the side of the valve close to the exporting device.

3. The transfer device according to claim 2, wherein the micro-component inlet is located between the gas flow inlet and the micro-component exporting port.

4. The transfer device according to claim 1, wherein the gas flow output device comprises:
a first pipeline, one end of the first pipeline being the gas flow outlet; and
a gas flow control unit connected to the other end of the first pipeline, wherein the gas flow control unit is used for controlling a flow quantity of the gas flow entering the first pipeline.

5. The transfer device according to claim 1, wherein the exporting device comprises:
a second pipeline comprising the micro-component inlet, the gas flow inlet, and the micro-component exportino port.

6. The transfer device according to claim 5. wherein the second pipeline comprises a first pipeline body and a first material, layer, the first material layer is provided on an inner wall of the first pipeline body, and a hydropathicity/hydrophobicity of a material of the first material layer is opposite to a hydropathicity/hydrophobicity of the solution.

7. The transfer device according to claim 5, wherein the micro-component source device comprises:
a third pipeline, wherein an outlet of the third pipeline is the micro-component outlet; and
a storage unit having an outlet in communication with an inlet of the third pipeline, wherein the storage unit is used for storing the solution and the micro-components.

8. The transfer device according to claim 7, wherein an angle between a central axis of the third pipeline and a central axis of the second pipeline is greater than 0° and less than 90°.

9. The transfer device according to claim 7, wherein the third pipeline comprises a second pipeline body and a second material layer, the second material layer is provided on an inner wall of the second pipeline body, and a hydropathi city/hydrophobicity of a material of the second material layer is opposite to a hydropathicity/hydrophobicity of the solution.

10. The transfer device according to claim 1, wherein there are a plurality of transfer units, and the plurality of transfer units are arranged at intervals in a predetermined direction, or the plurality of transfer units form a transfer unit matrix having multiple rows and multiple columns.

11. A transfer method applied in a transfer device comprising at least one transfer unit, wherein the transfer unit comprises: an exporting device comprising a gas flow inlet, a micro-component inlet and a micro-component exporting port which are in communication with each other: a micro-component source device comprising a micro-component outlet in communication with the micro-component inlet; and a gas flow output device comprising a gas flow outlet in communication with the gas flow inlet, and the transfer method comprises:
providing a predetermined structure;
storing a solution and one or more micro-components into the micro-component source device in the transfer device;
controlling the gas flow output device in the transfer device to output a gas flow at a predetermined flow quantity, such that a liquid drop of the solution carrying a micro-component is exported to a predetermined position of the predetermined structure; and
removing the solution.

12. The transfer method according to claim 11, wherein the transfer device further comprises a valve located on a connection pipeline between the micro-component outlet of the micro-component source device and the micro-component inlet of the exporting device, the gas flow output at the predetermined flow quantity causes the valve to open, such that a predetermined number of liquid drops enter the exporting device from the micro-component source device.

13. The transfer method according to claim 11, wherein removing the solution comprises:
heating the predetermined structure to evaporate the solution,

14. The transfer method according to claim 11, wherein a mass density of each of the one or more micro-components is greater than or equal to a mass density of the solution.

15. The transfer method according to claim 14, wherein each of the one or more micro components comprises a first part and a second part, the first part comprises an electrode, a mass density of the first part is greater than a mass density of the second part, and the mass density of the first part is greater than the mass density of the solution.

16. The transfer method according to claim 11, wherein each of the one or more micro-components comprises a body structure part, a first electrode and a second electrode, the body structure part is in a spherical shape, and the first electrode and the second electrode are located on a surface of the body structure part at intervals,

17. The transfer method according to claim 16, wherein the second electrode is located at the periphery of the first electrode, and the second electrode is an annular electrode; or the second electrode comprises a plurality of electrode parts spaced apart from each other, and lines connecting centers of the plurality of electrode parts form a closed figure.

18. The transfer method according to claim 17, wherein the predetermined position has a groove adapted to the micro-component, a metal channel and a metal hole are provided on the wall of the groove, and after the solution is removed, the metal hole is in contact with the first electrode and the metal channel is in contact with the second electrode.

19. The transfer method according to claim 18, wherein the metal channel is provided as a continuous annular metal channel, and the second electrode is provided in a shape which is able to comprise a plurality of spaced electrode parts.

20. The transfer device according to claim 4, wherein the gas flow control unit comprises a flow control valve and a controller, wherein the flow control valve is configured to control a flow quantity of the gas flow entering the first pipeline, and the controller is configured to send a control signal to the flow control valve, and the flow control valve is configured to adjust the degree of opening according to the control signal, so as to control the flow quantity of the gas flow in the first pipeline.
